(19) United States
(12) Patent Application Publication
(10) Pub. No.: US 2025/0245536 A1
(43) Pub. Date: Jul. 31, 2025

(54) RESONATOR QUBIT SYSTEM

(71) Applicant: NORTHROP GRUMMAN SYSTEMS CORPORATION, FALLS CHURCH, VA (US)

(72) Inventors: ANTHONY JOSEPH PRZYBYSZ, Linthicum, MD (US); CODY JAMES BALLARD, Catonsville, MD (US); KYLE MATTHEW CONNELLY, Baltimore, MD (US)

(21) Appl. No.: 18/427,131

(22) Filed: Jan. 30, 2024

(51) Int. Cl. G06N 10/40; B82Y 10/00; G01R 33/035; H10N 60/12

(52) U.S. Cl. CPC G06N 10/40; B82Y 10/00; G01R 33/0358; H10N 60/12

(57) ABSTRACT

One example includes a resonator qubit system. The system includes a resonator qubit having a first resonant frequency and an ancilla resonator having a second resonant frequency that is detuned relative to the first resonant frequency. The system also includes a tunable coupler interconnecting the resonator qubit and the ancilla resonator. The system further includes a tuning element configured to provide a tuning signal to the tunable coupler to provide a phase rotation of a quantum state of the resonator qubit based on the first and second resonant frequencies.

### GOVERNMENT INTEREST

The invention was made under Government Contract. Therefore, the U.S. Government has rights to the invention as specified in that contract.

### TECHNICAL FIELD

The present invention relates generally to computer systems, and specifically to a resonator qubit system.

### BACKGROUND

Quantum computers implement devices called qubits to provide manipulation of data, such as based on superpositions of quantum states. One characteristic of qubits is coherence, which can directly impact the fidelity with which a computer can implement a quantum operation. Qubit coherence can be affected by certain factors, such as the amplitude of the environmental noise that is coupled to the qubit, and the sensitivity of the qubit to the noise. As an example, the sensitivity to noise can be quantified as how a qubit's current or voltage operators shifts and couples the quantum states of the qubit. However, resonator qubits can be effective as qubits because they have relatively long coherence times due to their intrinsic characteristics. In particular, since the resonator frequency does not modulate with changes in the magnetic flux environment, resonator qubits can be particularly resilient to dephasing from flux noise.

### SUMMARY

One example includes a resonator qubit system. The system includes a resonator qubit having a first resonant frequency and an ancilla resonator having a second resonant frequency that is detuned relative to the first resonant frequency. The system also includes a tunable coupler interconnecting the resonator qubit and the ancilla resonator. The system further includes a tuning element configured to provide a tuning signal to the tunable coupler to provide a phase rotation of a quantum state of the resonator qubit based on the first and second resonant frequencies.

Another example includes a method for providing a phase rotation of a quantum state of a resonator qubit. The method includes stimulating the resonator qubit to operate at a first resonant frequency and stimulating an ancilla resonator to operate at a second resonant frequency that is detuned relative to the first resonant frequency. The method also includes activating a tuning element to provide a tuning signal having a predetermined energy amplitude to a tunable coupler interconnecting the resonator qubit and the ancilla resonator to provide frequency coupling between the resonator qubit and the ancilla resonator. The method further includes deactivating the tuning element after a predetermined duration of time that is based on the predetermined energy amplitude of the tuning signal to provide the phase rotation of the quantum state of the resonator qubit based on the first and second resonant frequencies.

Another example includes a resonator qubit system. The system includes a resonator qubit arranged as an inductor-capacitor (LC) resonator having a first resonant frequency and an ancilla resonator arranged as an LC resonator having a second resonant frequency that is detuned relative to the first resonant frequency. The system also includes a tunable coupler interconnecting the resonator qubit and the ancilla resonator. The system further includes a tuning element configured to provide a tuning signal to the tunable coupler to provide a phase rotation of a quantum state of the resonator qubit based on the first and second resonant frequencies as an addition of Berry phase to the resonator qubit.

### BRIEF DESCRIPTION OF THE DRAWINGS

FIG. 1 illustrates an example of a resonator qubit system.

FIG. 2 illustrates another example of a resonator qubit system.

FIG. 3 illustrates an example diagram of flux coupling.

FIG. 4 illustrates an example timing diagram.

FIG. 5 illustrates an example of a method for providing a phase rotation of a quantum state of a resonator qubit.

### DETAILED DESCRIPTION

The present invention relates generally to computer systems, and specifically to a resonator qubit system. The resonator qubit system can include a resonator qubit, an ancilla resonator, and a tunable coupler that interconnects the resonator qubit and ancilla resonator. As an example, the resonator qubit and the ancilla resonator can each be arranged as inductor-capacitor (LC) resonators that have resonant frequencies that are slightly detuned relative to each other. For example, the resonator qubit and the ancilla resonator can be arranged as approximately identical circuits with a slight change in inductance and/or capacitance to provide the detuning of resonant frequencies. The tunable coupler can be arranged as a DC superconducting quantum interference device (SQUID) that cross-couples the resonator qubit and the ancilla resonator.

The resonator qubit system also includes a tuning element that is configured to provide a tuning signal to the tunable coupler to control a phase rotation of a quantum state of the resonator qubit based on the resonant frequencies of the resonator qubit and the ancilla resonator. As an example, the tuning element can provide a control flux to the tunable coupler arranged as a DC SQUID to control a vacuum Rabi swap frequency between the resonator qubit and the ancilla resonator to provide the phase rotation of the quantum state of the resonator qubit. Based on providing the tuning signal at a predetermined energy for a predetermined duration of time (e.g., based on the predetermined energy), the tunable coupler can provide a phase rotation of the quantum state as an S-gate for the resonator qubit to accumulate Berry phase. Accordingly, the phase of the resonator qubit can be controlled for a qubit that is otherwise resilient to flux noise.

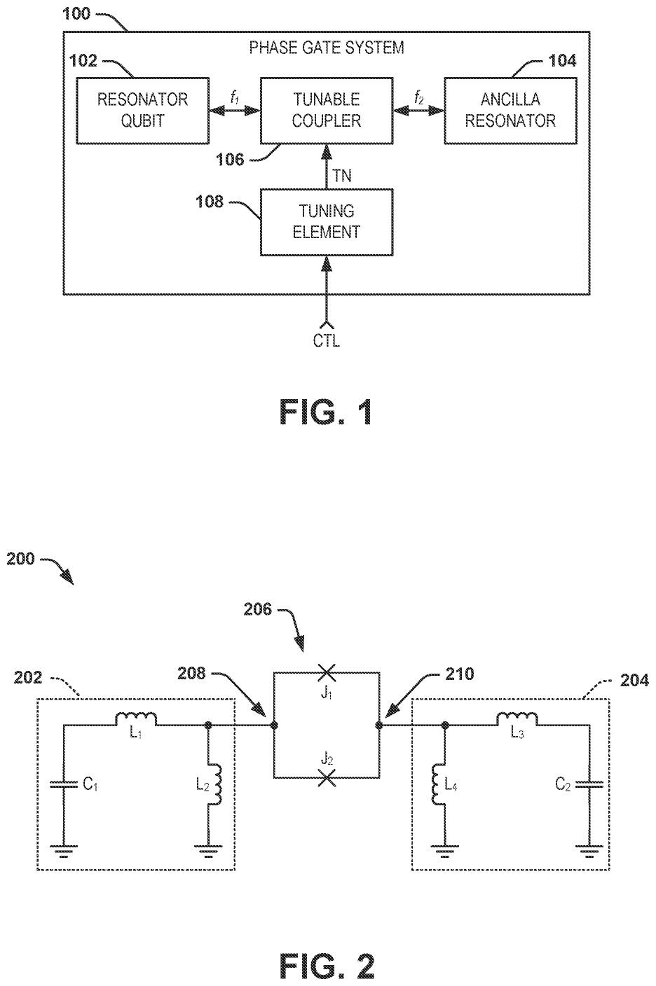

FIG. 1 illustrates an example of a resonator qubit system 100. The resonator qubit system 100 can be implemented in any of a variety of quantum computing environments to manipulate and store quantum data in a quantum computer system.

The resonator qubit system 100 includes a resonator qubit 102 and an ancilla resonator 104. The resonator qubit 102 can be stimulated to a first resonant frequency f₁ and the ancilla resonator 104 can be stimulated to a second resonant frequency f₂ that is slightly detuned from the first resonant frequency f₁. As an example, the first and second resonant frequencies f₁ and f₂ can be detuned by two orders of magnitude in the megahertz range. As an example, each of the resonator qubit 102 and the ancilla resonator 104 can be arranged as inductor-capacitor (LC) resonators, and can each be arranged as approximately identical circuits having a slightly different inductance and/or capacitance value to provide the detuning between the first and second resonant frequencies f₁ and f₂.

The resonator qubit system 100 also includes a tunable coupler 106 and a tuning element 108. The tunable coupler 106 is demonstrated as interconnecting the resonator qubit 102 and ancilla resonator 104. As an example, the tunable coupler 106 can be arranged as a DC superconducting quantum interference device (SQUID) that cross-couples the resonator qubit 102 and the ancilla resonator 104. Therefore, the tunable coupler 106 can provide a variable inductance between the resonator qubit 102 and the ancilla resonator 104 that can provide cross-coupling of the resonant frequencies f₁ and f₂ between the respective resonator qubit 102 and the ancilla resonator 104. As described in greater detail herein, the tuning element 108 is configured to provide a tuning signal TN to the tunable coupler 106 in response to a control signal CTL to control a phase rotation of a quantum state of the resonator qubit 102 based on the resonant frequencies f₁ and f₂ of the resonator qubit 102 and the ancilla resonator 104.

In the example of the tunable coupler 106 being arranged as a DC SQUID, the tuning element 108 can provide a variable flux to the tunable coupler 106 to vary the inductance of the tunable coupler 106. For example, the variable flux can operate as a control flux to control a vacuum Rabi swap frequency between the resonator qubit and the ancilla resonator to provide the phase rotation of the quantum state of the resonator qubit 102. The tuning signal TN can be controlled in both amplitude and time duration by the control signal CTL. Therefore, based on providing the tuning signal TN at a predetermined energy for a predetermined duration of time (e.g., inversely proportional), the tunable coupler 106 can provide a phase rotation of the quantum state as an S-gate for the resonator qubit 102 to accumulate Berry phase. As described herein the term “S-gate” refers to a π/2 rotation around the Z-axis of the Bloch sphere demonstrating the superposition of quantum states. As also described herein, the term “Berry phase” refers to the phase accumulated on the logical qubit state when the population rotates into and back out of a leakage state. Accordingly, the resonator qubit system 100 herein describes a system for a qubit that is resistant to dephasing resulting from flux noise, but for which a phase rotation of the quantum state can be provided.

FIG. 2 illustrates an example of a resonator qubit system 200. Similar to as described above, the resonator qubit system 200 can be implemented in any of a variety of quantum computing environments. The resonator qubit system 200 can correspond to the resonator qubit system 100 in the example of FIG. 1. Therefore, reference is to be made to the example of FIG. 1 in the following description of the example of FIG. 2.

The resonator qubit system 200 includes a resonator qubit 202. The resonator qubit 202 includes a grounded capacitor C₁, an inductor L₁ arranged in series with the capacitor C₁, and a grounded inductor L₂. Based on the capacitance value of the capacitor C₁ and the inductance values of the inductors L₁ and L₂, the resonator qubit 202 can be stimulated to a first resonant frequency f₁. The resonator qubit system 200 also includes an ancilla resonator 204. The ancilla resonator 204 includes a grounded capacitor C₂, an inductor L₃ arranged in series with the capacitor C₂, and a grounded inductor L₄. The ancilla resonator 204 is thus arranged structurally the same as the resonator qubit 202. Based on the capacitance value of the capacitor C₂ and the inductance values of the inductors L₃ and L₄, the ancilla resonator 204 can be stimulated to a second resonant frequency f₂ that is slightly detuned from the first resonant frequency f₁. As an example, the capacitance value of the capacitor C₂ and/or the inductance values of at least one of the inductors L₃ and La can be slightly different relative to the capacitance value of the capacitor C₁ and the inductance values of the inductors L₁ and L₂. As an example, the first and second resonant frequencies f₁ and f₂ can be detuned by two orders of magnitude in the megahertz range. For example, the first resonant frequency f₁ can be approximately 6.7 GHZ and the second resonant frequency f₂ can be approximately 6.73 GHZ, such that the first and second resonant frequencies f₁ and f₂ can be detuned by approximately 30 MHz.

The resonator qubit system 200 also includes a DC SQUID 206. The DC SQUID 206 includes a first Josephson junction J₁ and a second Josephson junction J₂ arranged in parallel with respect to each other. The DC SQUID 206 is coupled to the resonator qubit 202 at a node 208 that interconnects the inductors L₁ and L₂, and is coupled to the ancilla resonator 204 at a node 210 that interconnects the inductors L₃ and L₄. Therefore, the DC SQUID 206 can provide a variable inductance between the resonator qubit 202 and the ancilla resonator 204 that can provide cross-coupling of the resonant frequencies f₁ and f₂ between the respective resonator qubit 202 and the ancilla resonator 204.

As described above, the tuning element 108 (not demonstrated in the example of FIG. 2) is configured to provide a tuning signal TN as a control flux to the DC SQUID 206 to control a phase rotation of a quantum state of the resonator qubit 202 based on the resonant frequencies f₁ and f₂ of the resonator qubit 202 and the ancilla resonator 204. The control flux can thus control a coupling energy (e.g., in frequency) of the DC SQUID 206 to provide the coupling between the resonator qubit 202 and the ancilla resonator 204. The coupling can thus provide a complete phase rotation (e.g., π/2 rotation around the Z-axis of the superposition Bloch sphere) based on a combination of the coupling strength and the time of application of the control flux.

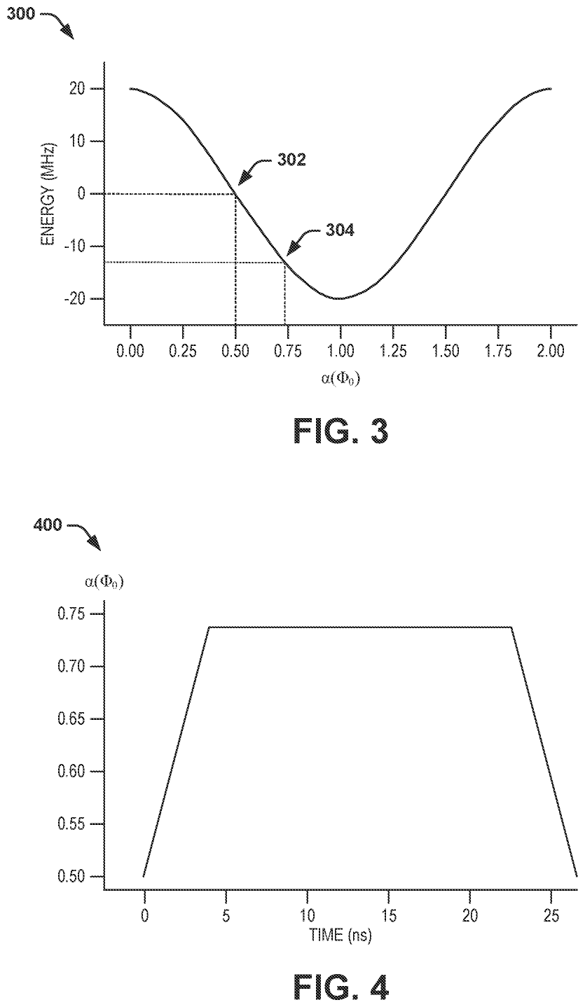

FIG. 3 illustrates an example diagram 300 of flux coupling. The diagram 300 demonstrates a plot of coupling energy in MHz as a function of control flux α (in flux quanta Φ₀) provided to the DC SQUID 206. The diagram 300 demonstrates the entirety of a cosine wave that defines energy as a function of flux Φ₀, demonstrating absolute value maximum energy at each integer multiple of Φ₀. The energy can correspond to a vacuum Rabi swap frequency (in MHz) between the resonator qubit 202 and the ancilla resonator 204. Therefore, the diagram 300 demonstrates coupling strength plotted as a function of flux Φ₀ generally. With respect to the example of FIG. 2, the control flux α provided to the DC SQUID 206 is provided by further example in FIG. 4.

FIG. 4 illustrates an example timing diagram 400. The timing diagram 400 defines a pulse of the tuning signal TN, and thus a control flux α pulse, that is provided to the DC SQUID 206, as a function of time (in nanoseconds). The timing diagram 400 thus demonstrates an amplitude of the control flux α (in flux quanta Φ₀) provided to the DC SQUID 206 as a function of time.

In the example of FIG. 4, the control flux α begins at an amplitude of 0.5Φ₀, which thus corresponds to complete deactivation of the DC SQUID 206 with respect to coupling between the resonator qubit 202 and the ancilla resonator 204. Therefore, at 0.5Φ₀, the DC SQUID 206 acts as an inductor with infinite inductance between the resonator qubit 202 and the ancilla resonator 204. With further reference to the diagram 300 in the example of FIG. 3, the initial flux α of 0.5Φ₀ is demonstrated at a point 302 corresponding to zero energy for the coupling strength. At 0 ns, the control flux α pulse is initialized and increases to an amplitude of approximately 0.74Φ₀ at approximately 4 ns. With further reference to the diagram 300 in the example of FIG. 3, the maximum amplitude of the control flux α pulse at approximately 0.74Φ₀ is demonstrated at a point 304 corresponding to approximately −12 MHz coupling energy. Therefore, the resonator qubit 202 begins to exhibit a phase rotation about the Z-axis in the Bloch sphere to accumulate Berry phase.

At approximately 23 ns, the control flux α pulse is deactivated to begin to decrease back down to approximately 0.5Φ₀ at approximately 27 ns. With further reference to the diagram 300 in the example of FIG. 3, the amplitude of the control flux α pulse decreases from approximately 0.74Φ₀ at the point 304 back to 0.5Φ₀ at the point 302. Upon conclusion of the control flux α pulse, the resonator qubit 202 has exhibited a complete phase rotation (e.g., a complete S-gate) about the Z-axis in the Bloch sphere to accumulate Berry phase.

As an example, the completion of the phase rotation can be based on application of the control flux α pulse at the specific coupling energy (e.g., approximately 0.74Φ₀) for the specific duration of time (e.g., approximately 19 ns). The amount of coupling energy and the duration of time demonstrated in the example of FIG. 4 is demonstrated as one example, such that different amounts of coupling energy and/or durations of time are possible. For example, the coupling energy and the duration of time of application of the control flux α pulse can be inversely proportional with respect to each other, such that any of a variety of approximately equal integral amount pulses are possible as described herein. Accordingly, shorter durations of the control flux α pulse at a higher coupling strength or longer durations of the control flux α pulse at shorter durations are likewise possible to achieve the same π/2 phase rotation, and thus the same accumulation of Berry phase. As another example, the amount of detuning between the resonator qubit 202 and the ancilla resonator 204 can vary, as well. As a result, a different coupling energy and/or a different duration of time of application of the control flux α pulse can be provided based on a variation of the difference in the resonant frequencies f₁ and f₂ of the resonator qubit 202 and the ancilla resonator 204, respectively.

As therefore described herein, the resonator qubit system 200 can correspond to a system for a qubit that is resistant to dephasing resulting from flux noise, but for which a phase rotation of the quantum state can be provided. By contrast, conventional qubits that are not implemented as a resonator qubit can be highly susceptible to flux noise, which can provide for a more rapid decoherence. On the other hand, conventional qubits that are implemented as a resonator qubit are unable to implement a phase gate for accumulation of phase, as described herein. Accordingly, the resonator qubit system 200 described herein exhibits superior qubit characteristics relative to conventional qubit systems.

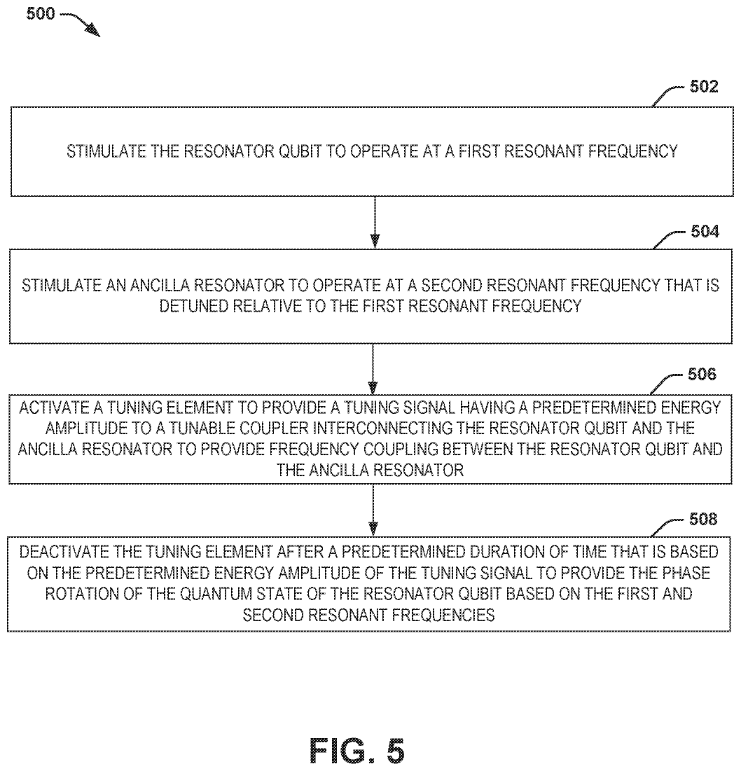

In view of the foregoing structural and functional features described above, a methodology in accordance with various aspects of the disclosure will be better appreciated with reference to FIG. 5. It is to be understood and appreciated that the method of FIG. 5 is not limited by the illustrated order, as some aspects could, in accordance with the present disclosure, occur in different orders and/or concurrently with other aspects from that shown and described herein. Moreover, not all illustrated features may be required to implement a methodology in accordance with an aspect of the present examples.

FIG. 5 illustrates an example of a method 500 for providing a phase rotation (e.g., an S-gate) of a quantum state of a resonator qubit (e.g., the resonator qubit 102). At 502, the resonator qubit is stimulated to operate at a first resonant frequency (e.g., the first resonant frequency f₁). At 504, an ancilla resonator (e.g., the ancilla resonator 104) is stimulated to operate at a second resonant frequency (e.g., the second resonant frequency f₂) that is detuned relative to the first resonant frequency. At 506, a tuning element (e.g., the tuning element 108) is activated to provide a tuning signal (e.g., the tuning signal TN) having a predetermined energy amplitude to a tunable coupler (e.g., the tunable coupler 106) interconnecting the resonator qubit and the ancilla resonator to provide frequency coupling between the resonator qubit and the ancilla resonator. At 508, the tuning element is deactivated after a predetermined duration of time that is based on the predetermined energy amplitude of the tuning signal to provide the phase rotation of the quantum state of the resonator qubit based on the first and second resonant frequencies.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. Additionally, where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

What is claimed is:

1. A resonator qubit system comprising:
a resonator qubit having a first resonant frequency;
an ancilla resonator having a second resonant frequency that is detuned relative to the first resonant frequency;
a tunable coupler interconnecting the resonator qubit and the ancilla resonator; and
a tuning element configured to provide a tuning signal to the tunable coupler to provide a phase rotation of a quantum state of the resonator qubit based on the first and second resonant frequencies.

2. The system of claim 1, wherein the tunable coupler is arranged as a cross-coupled DC superconducting quantum interference device (SQUID).

3. The system of claim 2, wherein the tuning element is configured as a flux generator configured to provide a variable flux to the cross-coupled DC SQUID.

4. The system of claim 1, wherein the tuning element is configured to provide the tuning signal to the tunable coupler to provide a predetermined energy to the tunable coupler to provide the phase rotation of the quantum state of the resonator qubit.

5. The system of claim 4, wherein the tuning element is configured to provide the tuning signal as a pulse at the predetermined energy for a predetermined duration of time that is based on an amplitude of the predetermined energy to provide the phase rotation of the quantum state of the resonator qubit.

6. The system of claim 1, wherein the tuning signal corresponds to a control flux provided to the tunable coupler to control a vacuum Rabi swap frequency between the resonator qubit and the ancilla resonator.

7. The system of claim 1, wherein the resonator qubit is configured as an inductor-capacitor (LC) resonator.

8. The system of claim 7, wherein the ancilla resonator is configured as an LC resonator that is arranged substantially the same as the resonator qubit with one of a different inductance or a different capacitance to provide the second resonant frequency that is detuned relative to the first resonant frequency.

9. The system of claim 1, wherein the tuning element is configured to provide the tuning signal to the tunable coupler to provide the phase rotation of the quantum state of the resonator qubit as an addition of Berry phase to the resonator qubit.

10. The system of claim 1, wherein the tuning element is configured to provide the tuning signal to the tunable coupler to provide an S-gate operation of the resonator qubit based on the first and second resonant frequencies.

11. A method for providing a phase rotation of a quantum state of a resonator qubit, the method comprising:
stimulating the resonator qubit to operate at a first resonant frequency;
stimulating an ancilla resonator to operate at a second resonant frequency that is detuned relative to the first resonant frequency;
activating a tuning element to provide a tuning signal having a predetermined energy amplitude to a tunable coupler interconnecting the resonator qubit and the ancilla resonator to provide frequency coupling between the resonator qubit and the ancilla resonator; and
deactivating the tuning element after a predetermined duration of time that is based on the predetermined energy amplitude of the tuning signal to provide the phase rotation of the quantum state of the resonator qubit based on the first and second resonant frequencies.

12. The method of claim 11, wherein activating the tuning element comprises activating the tuning element to provide the tuning signal as a variable flux to the tunable coupler configured as a cross-coupled DC superconducting quantum interference device (SQUID).

13. The method of claim 11, wherein activating the tuning element comprises activating the tuning element to provide the tuning signal as a control flux to control a vacuum Rabi swap frequency between the resonator qubit and the ancilla resonator.

14. The method of claim 11, wherein each of the resonator qubit and the ancilla resonator are configured as inductor-capacitor (LC) resonators.

15. The method of claim 11, wherein the tuning element is configured to provide the tuning signal to the tunable coupler to provide an S-gate operation of the resonator qubit based on the first and second resonant frequencies to accumulate a Berry phase of the resonator qubit.

16. A resonator qubit system comprising:
a resonator qubit arranged as an inductor-capacitor (LC) resonator having a first resonant frequency;
an ancilla resonator arranged as an LC resonator having a second resonant frequency that is detuned relative to the first resonant frequency;
a tunable coupler interconnecting the resonator qubit and the ancilla resonator; and
a tuning element configured to provide a tuning signal to the tunable coupler to provide a phase rotation of a quantum state of the resonator qubit based on the first and second resonant frequencies as an addition of Berry phase to the resonator qubit.

17. The system of claim 16, wherein the tunable coupler is arranged as a cross-coupled DC superconducting quantum interference device (SQUID), such that the tuning element is configured as a flux generator configured to provide a variable flux to the cross-coupled DC SQUID.

18. The system of claim 16, wherein the tuning element is configured to provide the tuning signal as a pulse at a predetermined energy to the tunable coupler for a predetermined duration of time that is based on an amplitude of the predetermined energy to provide the phase rotation of the quantum state of the resonator qubit.

19. The system of claim 16, wherein the tuning signal corresponds to a control flux provided to the tunable coupler to control a vacuum Rabi swap frequency between the resonator qubit and the ancilla resonator.

20. The system of claim 16, wherein the tuning element is configured to provide the tuning signal to the tunable coupler to provide an S-gate operation of the resonator qubit based on the first and second resonant frequencies.
